(19) United States
(12) Patent Application Publication
(10) Pub. No.: US 2025/0374585 A1
(43) Pub. Date: Dec. 4, 2025

(54) HIGH-ELECTRON-MOBILITY TRANSISTOR HAVING GROUP-III-NITRIDE CAPPING LAYER SEPARATED FROM CONTACT

(71) Applicant: MACOM Technology Solutions Holdings, Inc., Lowell, MA (US)

(72) Inventors: Kyoung-Keun Lee, Cary, NC (US); Fabian Radulescu, Chapel Hill, NC (US); Scott Sheppard, Chapel Hill, NC (US); Daniel Namishia, Wake Forest, NC (US)

(21) Appl. No.: 18/679,754

(22) Filed: May 31, 2024

(51) Int. Cl. H01L 29/778; H01L 29/20

(52) U.S. Cl. CPC H10D 30/47; H10D 62/8503

(57) ABSTRACT

Group-III-nitride high-electron-mobility transistors (HEMTs) are provided. A Group-III-nitride HEMT includes a substrate. The Group-III-nitride HEMT includes a barrier layer on the substrate. The Group-III-nitride HEMT includes a source contact and a drain contact that are on the barrier layer. Moreover, the Group-III-nitride HEMT includes a Group-III-nitride capping layer on the barrier layer and separated from the drain contact by a gap.

### TECHNICAL FIELD

The present disclosure generally relates to semiconductor devices and, more particularly, to high-electron-mobility transistors (HEMTs).

### BACKGROUND OF THE INVENTION

Electronic devices formed of low-bandgap semiconductor materials, such as silicon (Si) and gallium arsenide (GaAs), have found wide application in low-power and (in the case of Si) low-frequency applications. These semiconductor materials may be less well suited for high-power and/or high-frequency applications, however, because of their relatively small bandgaps (e.g., 1.12 eV for Si and 1.42 eV for GaAs at room temperature) and/or relatively small breakdown voltages.

For high-power, high-temperature and/or high-frequency applications, devices formed of wide-bandgap semiconductor materials, such as silicon carbide (SiC) (e.g., 2.996 eV bandgap for alpha SiC at room temperature) and Group-III nitrides (e.g., 3.36 eV bandgap for gallium nitride (GaN) at room temperature), are often used. These materials typically have higher electric-field breakdown strengths and higher electron-saturation velocities as compared to GaAs and Si.

A device of particular interest for high-power and/or high-frequency applications is the HEMT. HEMT devices may offer operational advantages under a number of circumstances because a two-dimensional electron gas (2DEG) is formed at the heterojunction of two semiconductor materials with different bandgap energies, where the smaller bandgap material has a higher electron affinity. The 2DEG is an accumulation layer in the smaller bandgap material and can contain a very high sheet-electron concentration. Additionally, electrons that originate in the wider-bandgap semiconductor can transfer to the 2DEG layer, allowing a high electron mobility due to reduced ionized-impurity scattering. This combination of high carrier concentration and high carrier mobility can give the HEMT a very large transconductance and may provide a strong performance advantage over metal-oxide-semiconductor field-effect transistors (MOSFETs) for high-frequency applications.

HEMTs fabricated with Group-III-nitride-based materials have the potential to generate large amounts of radio frequency (RF) power because of the combination of material characteristics that includes the aforementioned high breakdown fields, wide bandgaps, large conduction-band offset, and/or high saturated electron drift velocity. As used herein, the term “Group-III nitride” refers to semiconductor compounds formed with nitrogen (N) and elements in Group III of the periodic table, usually aluminum (Al), gallium (Ga), and/or indium (In). The term also refers to ternary and quaternary (or higher) compounds such as, for example, AlGaN and AlInGaN. As is understood by those in this art, Group-III elements can combine with N to form binary (e.g., GaN), ternary (e.g., AlGaN, AlInN), and quaternary (e.g., AlInGaN) compounds. These compounds all have empirical formulas in which one mole of N is combined with a total of one mole of the Group-III elements.

FIG. 1A is a schematic plan view of a conventional HEMT 100, and FIG. 1B is a schematic cross-sectional view of the HEMT 100 taken along a line A-A′ of FIG. 1A. As shown in FIG. 1B, the HEMT 100 may be formed on a substrate 110 such as, for example, a SiC substrate. An optional buffer layer 120 may be formed on an upper surface of the substrate 110, and a channel layer 130 is formed on top of the buffer layer 120. A barrier layer 140 is formed on top of the channel layer 130. The channel layer 130 and the barrier layer 140 may include Group-III-nitride-based materials, where the channel layer 130 has a bandgap that is less than a bandgap of the barrier layer 140. The substrate 110, the buffer layer 120, the channel layer 130, and the barrier layer 140 may together form a semiconductor stack structure 102.

A source contact 150 and a drain contact 152 are formed on an upper surface of the barrier layer 140 and are laterally spaced apart from each other in a first horizontal direction X. The source and drain contacts 150, 152 are typically metal contacts and configured to make ohmic contact with the semiconductor stack structure 102. The direction X is perpendicular to a second horizontal direction Y and a vertical direction Z. A gate 154 is formed on the upper surface of the barrier layer 140 between, in the direction X, the source contact 150 and the drain contact 152. A passivation layer 160 covers exposed portions of the upper surface of the barrier layer 140. A 2DEG layer 132 is formed at a junction between the channel layer 130 and the barrier layer 140 when the HEMT 100 is biased to be in its conducting (i.e., “on”) state. The 2DEG layer 132 acts as a highly conductive layer that allows current to flow between source and drain regions of the HEMT 100 that are beneath the source contact 150 and the drain contact 152, respectively.

Defects along or near the upper surface of the semiconductor stack structure 102 (which may be referred to herein as defects “at” the upper surface of the semiconductor stack structure 102) may form electron traps that capture charge during operation of the HEMT 100. This trapped charge may collect at an interface between the passivation layer 160 and the barrier layer 140 in regions between the source contact 150 and the gate 154 and between the gate 154 and the drain contact 152, and this trapped charge may reduce current flow through the 2DEG layer 132. The charge in the electron traps may be dissipated through the use of a multi-layer passivation structure that is formed on the upper surface of the semiconductor stack structure 102 between the source contact 150 and the drain contact 152 in the HEMT 100. For example, a multi-layer passivation structure may replace the passivation layer 160. Examples of multi-layer passivation structures are described in U.S. Pat. No. 10,937,873 to Lee et al., the disclosure of which is incorporated herein in its entirety.

### SUMMARY OF THE INVENTION

A Group-III-nitride HEMT, according to some embodiments herein, may include a substrate and a channel layer on the substrate. The Group-III-nitride HEMT may include a barrier layer on the channel layer. The Group-III-nitride HEMT may include a source contact and a drain contact that are on the barrier layer. Moreover, the Group-III-nitride HEMT may include a Group-III-nitride capping layer on the barrier layer and including a first sidewall and a second sidewall that are between the source contact and the drain contact. The first sidewall of the Group-III-nitride capping layer may face the source contact. The second sidewall of the Group-III-nitride capping layer may face the drain contact and may be spaced apart from the drain contact.

A Group-III-nitride HEMT, according to some embodiments herein, may include a substrate and a barrier layer on the substrate. The Group-III-nitride HEMT may include a source contact and a drain contact that are on the barrier layer. Moreover, the Group-III-nitride HEMT may include a Group-III-nitride capping layer on the barrier layer and separated from the source contact by a first gap and from the drain contact by a second gap.

A Group-III-nitride HEMT, according to some embodiments herein, may include a substrate and a barrier layer on the substrate. The Group-III-nitride HEMT may include a source contact and a drain contact that are on the barrier layer. The Group-III-nitride HEMT may include a Group-III-nitride capping layer on the barrier layer, between the source contact and the drain contact. Moreover, the Group-III-nitride HEMT may include a gate on the Group-III-nitride capping layer. The Group-III-nitride capping layer may be spaced apart from the source contact by a first distance that is a first percentage of a third distance between the source contact and the gate. The Group-III-nitride capping layer may be spaced apart from the drain contact by a second distance that is a second percentage of a fourth distance between the drain contact and the gate. The first percentage and the second percentage may each be at least 1%.

### BRIEF DESCRIPTION OF THE DRAWINGS

FIG. 1A is a schematic plan view of a conventional HEMT.

FIG. 1B is a schematic cross-sectional view taken along the line A-A′ of FIG. 1A.

FIG. 2A is a schematic cross-sectional view of a HEMT according to embodiments of the present invention.

FIG. 2B is an enlarged view of an upper portion of FIG. 2A.

FIGS. 3A and 3B are graphs illustrating how the drain-to-source current of a HEMT may change over time after an RF pulse input.

### DETAILED DESCRIPTION

Embodiments of the present invention are directed to HEMTs having reduced trapped charge. Defect-oriented trapped charge can cause output-signal distortion in semiconductor devices such as Group-III-nitride-based RF transistor amplifiers. Conventional GaN-HEMT-based semiconductor devices include an additional top layer of film (e.g., one or more passivation layers or other capping layers) on top of an AlGaN/GaN HEMT epitaxial structure for better charge distribution near a gate metal to improve device performance.

Embodiments of the present invention include a Group-III-nitride capping layer that can be patterned to reduce trapped charge, and thus to improve device performance. For example, the Group-III-nitride capping layer may be patterned (e.g., etched) such that it is spaced apart from a drain contact that faces the Group-III-nitride capping layer. The Group-III-nitride capping layer may therefore also be referred to herein as a “patterned capping layer” (or a “patterned top layer”). Devices having the patterned capping layer can demonstrate reduced drain-current drop during RF-pulse measurement, thereby indicating improved transient behaviors.

Embodiments of the present invention will now be described in greater detail with reference to the figures.

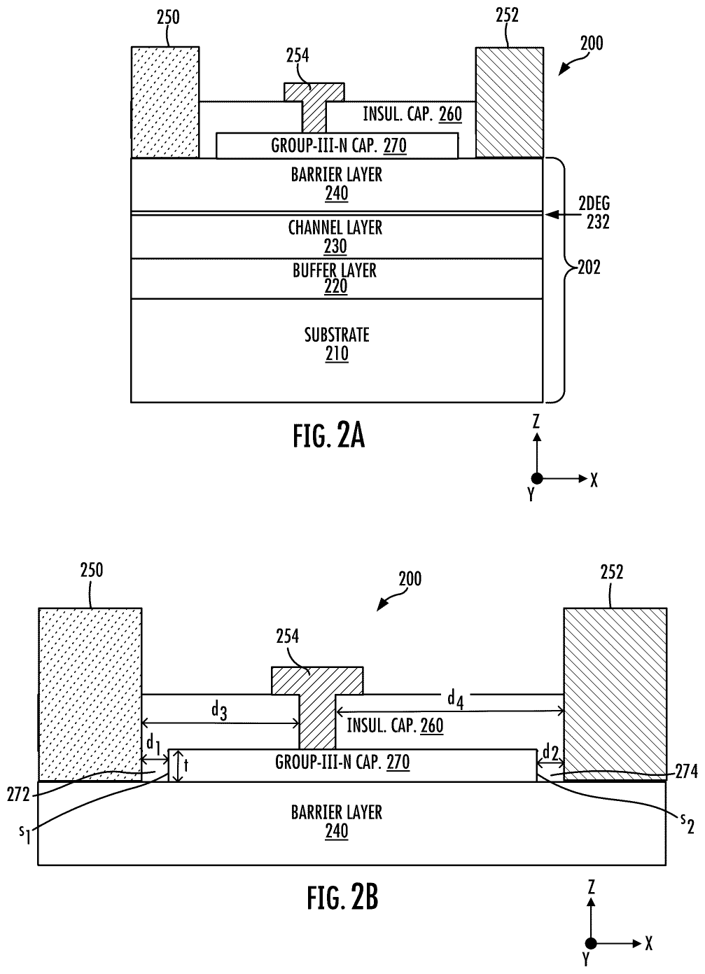

FIG. 2A is a schematic cross-sectional view of a HEMT 200 according to embodiments of the present invention. The HEMT 200 includes a Group-III-nitride capping layer 270 that is on an upper surface of a semiconductor stack structure 202. A source contact 250 and a drain contact 252 are also on the upper surface of the semiconductor stack structure 202, and the Group-III-nitride capping layer 270 is between the source contact 250 and the drain contact 252 in the direction X. The Group-III-nitride capping layer 270 is spaced apart from at least one of the source contact 250 or the drain contact 252 in the direction X. This spacing helps to compensate for charge traps in the HEMT 200, as it can better redistribute charge in the Group-III-nitride capping layer 270, such as by changing the flow of charge.

A gate (e.g., gate electrode) 254 and an insulating capping layer 260 are on an upper surface of the Group-III-nitride capping layer 270. Additional details about the Group-III-nitride capping layer 270, the insulating capping layer 260, and the gate 254 are described herein with respect to FIG. 2B. One or more further insulating capping layers may be on top of the insulating capping layer 260. For simplicity of illustration, however, such additional layers are omitted from view in FIG. 2A.

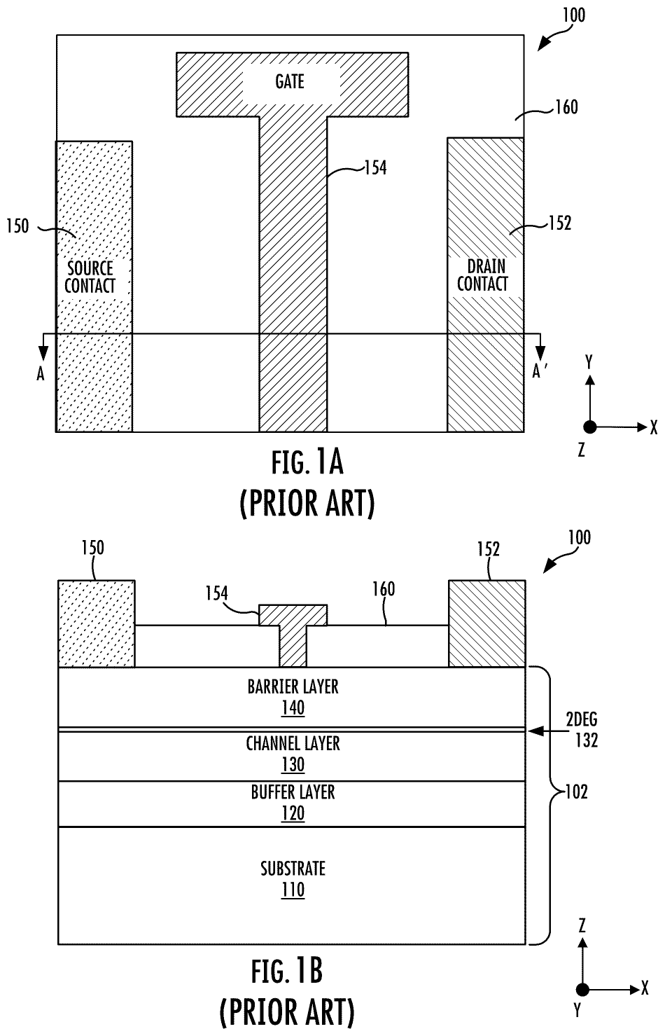

The semiconductor stack structure 202 may be analogous to the semiconductor stack structure 102 shown in FIG. 1B. Accordingly, the semiconductor stack structure 202 includes a substrate 210, an optional buffer (and/or nucleation/transition) layer 220 on an upper surface of the substrate 210, a channel layer 230 on an upper surface of the optional layer 220, and a barrier layer 240 on an upper surface of the channel layer 230. In some embodiments, the optional layer 220, the channel layer 230, and/or the barrier layer 240 may be epitaxially grown on the upper surface of the substrate 210.

A 2DEG layer 232 is at a junction between the channel layer 230 and the barrier layer 240 when the HEMT 200 is biased to be in its conducting (i.e., “on”) state. The 2DEG layer 232 acts as a highly conductive layer that allows conduction between source and drain regions of the HEMT 200 that are beneath the source contact 250 and the drain contact 252, respectively. Moreover, the source contact 250 and the drain contact 252 are spaced apart from each other in the direction X on an upper surface of the barrier layer 240.

The substrate 210 may be, for example, a SiC substrate. Other examples of materials that may be suitable for the substrate 210 include sapphire, aluminum nitride (AlN), AlGaN, GaN, Si, GaAs, lithium gallate (LGO), zinc oxide (ZnO), lanthanum aluminum oxide (LAO), and indium phosphide (InP).

One or more optional layers 220 such as, for example, buffer, nucleation and/or transition layers, may be formed on the upper surface of the substrate 210. As an example, an AlN buffer layer 220 may be formed on the upper surface of the substrate 210 to provide an appropriate crystal structure transition between the SiC substrate 210 and the remainder of the HEMT 200. Strain balancing transition layer(s) 220 may also and/or alternatively be provided as described, for example, in U.S. Patent Publication No. 2003/0102482 A1, the disclosure of which is incorporated herein by reference in its entirety. The optional buffer/nucleation/transition layers 220 may be deposited by metal organic chemical vapor deposition (MOCVD) or by other techniques known to those of skill in the art, such as molecular beam epitaxy (MBE) or high vapor pressure epitaxy (HVPE).

The channel layer 230 is formed on the upper surface of the substrate 210 (or on the optional layers 220), and the barrier layer 240 is formed on an upper surface of the channel layer 230. The channel layer 230 may have a bandgap that is less than the bandgap of the barrier layer 240, and the channel layer 230 may also have a larger electron affinity than the barrier layer 240. The channel layer 230 and the barrier layer 240 may include Group-III-nitride-based materials.

In some embodiments, the channel layer 230 may be a Group-III nitride, such as AlₓGa₁₋ₓN, where 0≤x<1, provided that the energy of the conduction-band edge of the channel layer 230 is less than the energy of the conduction-band edge of the barrier layer 240 at an interface between the channel layer 230 and the barrier layer 240. In certain embodiments of the present invention, x=0, indicating that the channel layer 230 is GaN. The channel layer 230 may also be other Group-III-nitrides, such as InGaN or AlInGaN. The channel layer 230 may be undoped (“unintentionally doped”) and may be grown to a thickness of greater than about 20 angstroms (Å). The channel layer 230 may also be a multi-layer structure, such as a superlattice or combinations of GaN or AlGaN. The channel layer 230 may be under compressive strain in some embodiments.

According to some embodiments, the barrier layer 240 is AlN, AlInN, AlGaN, or AlInGaN, or combinations of layers thereof. The barrier layer 240 may comprise a single layer or may be a multi-layer structure. In particular embodiments of the present invention, the barrier layer 240 may be sufficiently thick and may have a sufficiently high Al composition and doping to induce a significant carrier concentration at the interface between the channel layer 230 and the barrier layer 240 through polarization effects when the barrier layer 240 is buried under ohmic contact metal. The barrier layer 240 may, for example, be from about 0.1 nanometer (nm) to about 30 nm thick, but is not so thick as to cause cracking or substantial defect formation therein. Barrier layer thicknesses in the range of 15-30 nm are common. In certain embodiments, the barrier layer 240 is undoped or doped with an n-type dopant to a concentration less than about 10¹⁹ cm⁻³. In some embodiments of the present invention, the barrier layer 240 is AlₓGa₁₋ₓN, where 0<x<1. In particular embodiments, the Al concentration is about 25%. In other embodiments of the present invention, the barrier layer 240 comprises AlGaN with an Al concentration of between about 5% and about 100%. In specific embodiments of the present invention, the Al concentration is greater than about 10%. The channel layer 230 and/or the barrier layer 240 may be deposited, for example, by MOCVD, MBE or HVPE.

The HEMT 200 may be a GaN-based device or another Group III-nitride-based device, due to a semiconductor material of the channel layer 230 and/or the barrier layer 240. The HEMT 200 may thus be referred to herein as a “Group III-nitride” HEMT. Moreover, the source contact 250 and the drain contact 252 may include a metal, such as titanium aluminum nitride (TiAlN), that can form an ohmic contact to a GaN-based semiconductor material.

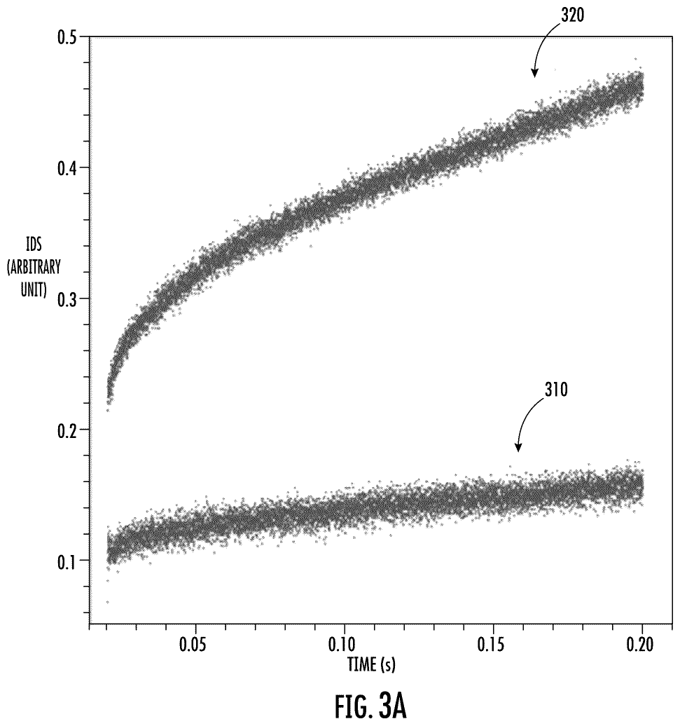

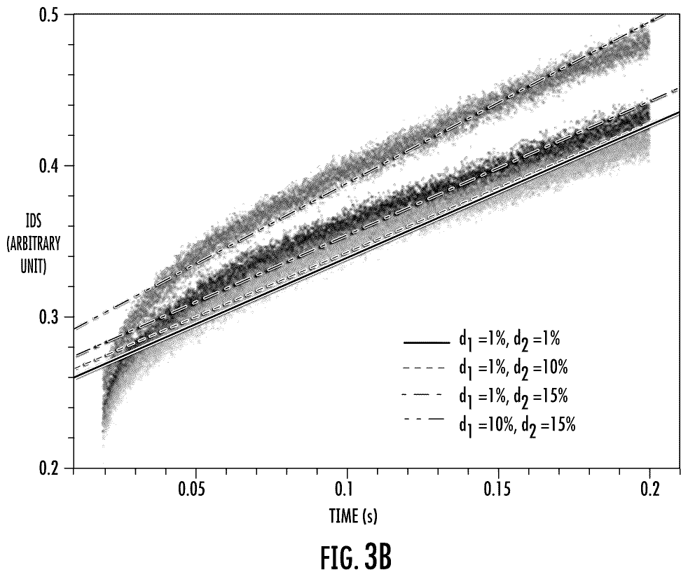

The HEMT 200 may be configured as a normally-on HEMT or as a normally-off HEMT. A normally-off HEMT is configured so that when the source and drain contacts 250, 252 are appropriately biased and no bias voltage is applied to the gate 254, the HEMT 200 will not conduct current between the source and drain contacts 250, 252. In contrast, a normally-on HEMT is configured so that when the source and drain contacts 250, 252 are appropriately biased and no bias voltage is applied to the gate 254, the HEMT 200 will conduct current between the source and drain contacts 250, 252. A normally-off HEMT may thus be turned on (i.e., made conducting) by applying a bias voltage to the gate 254, and a normally-on HEMT may be turned off (i.e., made non-conducting) by applying a bias voltage to the gate 254. In some embodiments, the primary on-state conduction path in the HEMT 200 may be a conduction path that is formed in the 2DEG layer 232 that allows a drain-to-source current I_{ds} (FIG. 3B) to flow between the drain contact 252 and the source contact 250.

FIG. 2B is an enlarged view of an upper portion of FIG. 2A. As shown in FIG. 2B, the Group-III-nitride capping layer 270 includes a first sidewall s₁ and a second sidewall s₂ that are on opposite sides in the direction X between the source contact 250 and the drain contact 252. The first sidewall s₁ faces the source contact 250 in the direction X, and the second sidewall s₂ faces the drain contact 252 in the direction X.

The insulating capping layer 260 may be on at least one of the first sidewall s₁ or the second sidewall s₂, as the Group-III-nitride capping layer 270 may be patterned to provide (i) a first gap 272 between the Group-III-nitride capping layer 270 and the source contact 250 and/or (ii) a second gap 274 between the Group-III-nitride capping layer 270 and the drain contact 252, and the insulating capping layer 260 may be in the gaps 272, 274. For example, the insulating capping layer 260 may comprise silicon nitride (e.g., Si₃N₄) that is deposited to fill the gaps 272, 274, in addition to being formed on an upper surface of the Group-III-nitride capping layer 270. In some embodiments, the insulating capping layer 260 may include a first portion (in the first gap 272) that contacts a first portion of the upper surface of the barrier layer 240 (adjacent the source contact 250) and/or a second portion (in the second gap 274) that contacts a second portion of the upper surface of the barrier layer 240 (adjacent the drain contact 252). The first gap 272 is between the first sidewall s₁ and the source contact 250 in the direction X, and the second gap 274 is between the second sidewall s₂ and the drain contact 252 in the direction X. As a result of the first gap 272, the first sidewall s₁ may be spaced apart (i.e., separated from) from the source contact 250 by a first distance d₁ in the direction X. Similarly, as a result of the second gap 274, the second sidewall s₂ may be spaced apart from the drain contact 252 by a second distance d₂ in the direction X.

The gaps 272, 274, which may also be referred to herein as “recesses,” can compensate for charge traps in the HEMT 200 by better redistributing charge in the Group-III-nitride capping layer 270, and can thereby improve performance of the HEMT 200. Patterning the Group-III-nitride capping layer 270 to form the gaps 272, 274 may include etching (e.g., dry-etching after photomask patterning) the Group-III-nitride capping layer 270. In some embodiments, one of the first gap 272 or the second gap 274 may be omitted. Accordingly, the first sidewall s₁ may be in contact with the source contact 250 or the second sidewall s₂ may be in contact with the drain contact 252.

Magnitudes of the distances d₁, d₂ can impact how effectively the gaps 272, 274 compensate for charge traps, as described in further detail herein with respect to FIG. 3B. Moreover, the magnitude of the second distance d₂ may, according to some embodiments, contribute more to compensating for charge traps than the first distance d₁. The second gap 274 may thus provide a larger benefit than the first gap 272, which may therefore be omitted in some embodiments.

A typical distance d₃ between the gate 254 and the source contact 250 is about 1 μm, and a typical distance d₄ between the gate 254 and the drain contact 252 is about 4 μm. Accordingly, the distance d₁ (which is less than the distance d₃) is typically less than 1 μm, and the distance d₂ (which is less than the distance d4) is typically less than 4 μm. According to some embodiments, the distance d₁ may range from about 0.01 μm to about 0.14 μm, and the distance d₂ may range from about 0.04 μm to about 0.76 μm. In other embodiments, the distances d₁, d₂ may be longer or shorter, depending on device design. For example, device design may determine (a) the distances d₃, d₄, (b) what percentage the distance d₁ is of the distance d₃, and/or (c) what percentage the distance d₂ is of the distance d₄.

In some embodiments, the insulating capping layer 260 may contact (i) the sidewall s₂ (and/or the sidewall s₁), (ii) the upper surface of the Group-III-nitride capping layer 270, (iii) a sidewall of the drain contact 252 (and/or a sidewall of the source contact 250), and (iv) the upper surface of the barrier layer 240. Moreover, the gate 254 is a conductive (e.g., metal) gate that is electrically connected to the Group-III-nitride capping layer 270. For example, the gate 254 may be on (e.g., may contact) the upper surface of the of the Group-III-nitride capping layer 270. According to some embodiments, the gate 254 may be on the upper surface of the insulating capping layer 260 and may extend into the insulating capping layer 260. As an example, the gate 254 may be a T-shaped gate.

The gate 254 may, in some embodiments, be closer to the source contact 250 than the drain contact 252. A third distance d₃ between, in the direction X, a sidewall of the source contact 250 and a first sidewall of the gate 254 may thus be shorter than a fourth distance d₄ between, in the direction X, a sidewall of the drain contact 252 and a second sidewall of the gate 254. The first and second sidewalls of the gate 254 may be lower sidewalls that contact the insulating capping layer 260.

The Group-III-nitride capping layer 270 has a thickness t in the vertical direction Z. According to some embodiments, the thickness t may be less than 5 nm. For example, the thickness t may range from 2-4 nm. In other embodiments, the thickness t may be more than 5 nm. The contacts 250, 252 may each be about 1 micrometer (um) thick in the direction Z, and thus may be much thicker than the thickness t. The thickness t may also be thinner than a thickness, in the direction Z, of the barrier layer 240. Alternatively, the thickness t may be thicker than the barrier layer 240. In some embodiments, a lower surface of the Group-III-nitride capping layer 270 may be coplanar with a lower surface of the source contact 250 and a lower surface of the drain contact 252, as those three lower surfaces may all be in contact with the upper surface of the barrier layer 240.

The Group-III-nitride capping layer 270 may comprise a different semiconductor material from that of the barrier layer 240. For example, the Group-III-nitride capping layer 270 may comprise GaN, and the barrier layer 240 may comprise AlGaN. The barrier layer 240 may thus include Al, and the Group-III-nitride capping layer 270 does not include Al. The Group-III-nitride capping layer 270 is not limited, however, to GaN. Rather, the Group-III-nitride capping layer 270 may comprise, for example, low-Al AlGaN (having a lower Al content than the barrier layer 240), AlN, InGaN, or other Group-III nitrides. Moreover, the Group-III-nitride capping layer 270 may comprise Si-doped GaN, iron (Fe)-doped GaN, or unintentionally-doped GaN. Doping the Group-III-nitride capping layer 270 with Fe may better compensate for charge traps than other dopants (e.g., carbon (C)), and Fe-doping may thus result in a faster response by the HEMT 200 to an RF pulse input than C-doping.

In some embodiments, the Group-III-nitride capping layer 270 may be epitaxially grown from the semiconductor stack structure 202 (e.g., from the barrier layer 240). Accordingly, the Group-III-nitride capping layer 270 may be the uppermost epitaxial semiconductor layer of the HEMT 200, and thus may also be referred to herein as a “top layer,” “top epitaxial layer,” or “top semiconductor layer.”

FIGS. 3A and 3B are graphs illustrating how the drain-to-source current I_{ds} of a HEMT may change over time after providing an RF pulse input to the HEMT. FIG. 3A shows (i) a first scatter plot 310 for a HEMT that includes a non-patterned Group-III-nitride capping layer and (ii) a second scatter plot 320 for a HEMT that includes a patterned capping layer, such as the Group-III-nitride capping layer 270 that is shown in FIG. 2B. In contrast with the patterned capping layer, the non-patterned capping layer lacks gaps 272, 274 (FIG. 2B), and thus is in contact with both a source contact and a drain contact.

Due to the presence of the gaps 272, 274 in the patterned capping layer, the current I_{ds} may recover significantly faster in the HEMT that includes the patterned capping layer (as shown by the scatter plot 320) than in the HEMT that includes the non-patterned capping layer (as shown by the scatter plot 310). The recovery times shown in FIG. 3A indicate transient behaviors of HEMTs in response to an RF pulse input. The RF pulse input may be, for example, a square wave and may result in an initial drop in the current I_{ds} from about 0.8 (in arbitrary units) to about 0.1 (with the non-patterned capping layer) or about 0.2 (with the patterned capping layer). The smaller initial drop in drain current when using the patterned capping layer can induce a faster recovery time. By about 0.2 seconds after the RF pulse input, the scatter plot 320 shows that the current I_{ds} has recovered to above 0.4, whereas the scatter plot 310 shows that the current I_{ds} is still below 0.2. A faster recovery time means reduced trapping charge with RF-pulse input stress, indicating better device performance.

FIG. 3B shows transient behaviors of a HEMT that includes a patterned capping layer, such as the Group-III-nitride capping layer 270 that is shown in FIG. 2B, with various distances d₁, d₂ from the source contact 250 (FIG. 2B) and the drain contact 252 (FIG. 2B), respectively. The values of d₁ and d₂ are shown as percentages in FIG. 3B, where the first distance d₁ is a percentage of the third distance d₃ (FIG. 2B) between the source contact 250 and the gate 254 (FIG. 2B) and the second distance d₂ is a percentage of the fourth distance d₄ (FIG. 2B) between the drain contact 252 and the gate 254.

The distances d₁, d₂ may each be at least 1%, or even at least 10%. In some embodiments, the percentage value of the second distance d₂ may be larger than the percentage value of the first distance di. Moreover, the current I_{ds} may recover faster when the second distance d₂ is at least 10%. As an example, FIG. 3B shows a faster recovery when increasing the second distance d₂ from 1% to 10%, and a still faster recovery when increasing the second distance d₂ from 10% to 15%. The fastest recovery shown in FIG. 3B is when the first distance d₁ is 10% and the second distance d₂ is 15%. The distances d₁, d₂, however, are not limited to the example percentage values shown in FIG. 3B. For example, the first distance d₁ may be in a range of 6-14%, and the second distance d₂ may be in a range of 11-19%. According to some embodiments, the second distance d₂ may be at least 15% and the first distance d₁ may be less than 15%.

Transient HEMT behaviors, such as those shown in FIGS. 3A and 3B, may be measured by a system that includes, for example, an RF pulse input, an input matching network, a device-under-test (DUT), an output matching network, and a load. The RF pulse input may be provided to the DUT via the input matching network. Moreover, the output matching network may be coupled between the DUT and the load, and an output may be measured at a node that is coupled between the output matching network and the load. For example, the DUT may be a HEMT 200, and the measured output may be the I_{ds} of the HEMT 200 over time in response to the RF pulse input. Accordingly, the system can measure a drain-current response (over time) to the RF pulse that is input into an input-output matched DUT such as the HEMT 200.

HEMTs 200 (FIG. 2A) according to some embodiments herein may provide a number of advantages. These advantages may include compensating for charge traps in a HEMT 200 by including a Group-III-nitride capping layer 270 (FIG. 2B) that is patterned to have a gap 272 (FIG. 2B) and/or a gap 274 (FIG. 2B). The gaps 272, 274 can change the flow of charge to better redistribute charge in the Group-III-nitride capping layer 270. As a result, the HEMT 200 having the Group-III-nitride capping layer 270 can benefit from a smaller drain-current drop during an RF-pulse measurement, thereby indicating improved transient behavior of the HEMT 200. An example of transient-behavior improvement is shown in FIG. 3A.

Example embodiments are described herein with reference to the accompanying drawings. Many different forms and embodiments are possible without deviating from the teachings of this disclosure and so the disclosure should not be construed as limited to the example embodiments set forth herein. Rather, these example embodiments are provided so that this disclosure will be thorough and complete, and will convey the scope of the present invention to those skilled in the art. In the drawings, the sizes and relative sizes of layers and regions may be exaggerated for clarity. Like reference numbers refer to like elements throughout.

Example embodiments are described herein with reference to cross-sectional illustrations that are schematic illustrations of idealized embodiments and intermediate structures of example embodiments. As such, variations from the shapes of the illustrations as a result, for example, of manufacturing techniques and/or tolerances, are to be expected. Thus, embodiments herein should not be construed as limited to the particular shapes illustrated herein but may include deviations in shapes that result, for example, from manufacturing.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including,” when used in this specification, specify the presence of the stated features, steps, operations, elements, and/or components, but do not preclude the presence or addition of one or more other features, steps, operations, elements, components, and/or groups thereof.

It will be understood that when an element is referred to as being “coupled,” “connected,” or “responsive” to, or “on,” another element, it can be directly coupled, connected, or responsive to, or on, the other element, or intervening elements may also be present. In contrast, when an element is referred to as being “directly coupled,” “directly connected,” or “directly responsive” to, or “directly on,” another element, there are no intervening elements present. As used herein, the term “and/or” includes any and all combinations of one or more of the associated listed items. Moreover, the symbol “/” (e.g., when used in the term “source/drain”) will be understood to be equivalent to the term “and/or.”

It will be understood that although the terms “first,” “second,” etc. may be used herein to describe various elements, these elements should not be limited by these terms. These terms are only used to distinguish one element from another. Thus, a first element could be termed a second element without departing from the teachings of the present embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if a device in the figures is turned over, elements described as “below” or “beneath” other elements or features would then be oriented “above” the other elements or features. Thus, the term “below” can encompass both an orientation of above and below. The device may be otherwise oriented (e.g., rotated 90 degrees or at other orientations) and the spatially relative descriptors used herein may be interpreted accordingly.

Many different embodiments have been disclosed herein, in connection with the above description and the drawings. It will be understood that it would be unduly repetitious and obfuscating to literally describe and illustrate every combination and subcombination of these embodiments. Accordingly, the present specification, including the drawings, shall be construed to constitute a complete written description of all combinations and subcombinations of the embodiments described herein, and of the manner and process of making and using them, and shall support claims to any such combination or subcombination.

The above-disclosed subject matter is to be considered illustrative, and not restrictive, and the appended claims are intended to cover all such modifications, enhancements, and other embodiments, which fall within the scope of the present invention. Thus, to the maximum extent allowed by law, the scope is to be determined by the broadest permissible interpretation of the following claims and their equivalents, and shall not be restricted or limited by the foregoing detailed description.

What is claimed is:

1. A Group-III-nitride high-electron-mobility transistor (HEMT) comprising:
a substrate;
a channel layer on the substrate;
a barrier layer on the channel layer;
a source contact and a drain contact that are on the barrier layer; and
a Group-III-nitride capping layer on the barrier layer, the Group-III-nitride capping layer including a first sidewall and a second sidewall between the source contact and the drain contact,
wherein the first sidewall of the Group-III-nitride capping layer faces the source contact, and
wherein the second sidewall of the Group-III-nitride capping layer faces the drain contact and is spaced apart from the drain contact.

2. The Group-III-nitride HEMT of claim 1, further comprising a gate on the Group-III-nitride capping layer,
wherein the second sidewall of the Group-III-nitride capping layer is spaced apart from the drain contact by at least 1% of a distance between the drain contact and the gate.

3. The Group-III-nitride HEMT of claim 2, wherein the second sidewall of the Group-III-nitride capping layer is spaced apart from the drain contact by 11-19% of the distance between the drain contact and the gate.

4. The Group-III-nitride HEMT of claim 2, wherein the first sidewall of the Group-III-nitride capping layer is in contact with the source contact.

5. The Group-III-nitride HEMT of claim 2, wherein the first sidewall of the Group-III-nitride capping layer is spaced apart from the source contact.

6. The Group-III-nitride HEMT of claim 5, wherein the first sidewall of the Group-III-nitride capping layer is spaced apart from the source contact by at least 1% of a distance between the source contact and the gate.

7. The Group-III-nitride HEMT of claim 6, wherein the first sidewall of the Group-III-nitride capping layer is spaced apart from the source contact by 6-14% of the distance between the source contact and the gate.

8. The Group-III-nitride HEMT of claim 6, wherein the first sidewall of the Group-III-nitride capping layer is spaced apart from the source contact by a smaller percentage of the distance between the source contact and the gate than a percentage of the distance between the drain contact and the gate by which the second sidewall of the Group-III-nitride capping layer is spaced apart from the drain contact.

9. The Group-III-nitride HEMT of claim 1, further comprising an insulating capping layer that is on an upper surface of the Group-III-nitride capping layer and between the second sidewall of the Group-III-nitride capping layer and the drain contact.

10. The Group-III-nitride HEMT of claim 1, wherein the Group-III-nitride capping layer is thinner than the barrier layer.

11. The Group-III-nitride HEMT of claim 10, wherein a thickness of the Group-III-nitride capping layer is less than 5 nanometers (nm).

12. The Group-III-nitride HEMT of claim 1, wherein the Group-III-nitride capping layer includes gallium nitride (GaN).

13. The Group-III-nitride HEMT of claim 1, wherein a material of the Group-III-nitride capping layer is different from a material of the barrier layer.

14. The Group-III-nitride HEMT of claim 13, wherein the material of the barrier layer includes aluminum (Al) and the material of the Group-III-nitride capping layer does not include Al.

15. A Group-III-nitride high-electron-mobility transistor (HEMT) comprising:
a substrate;
a barrier layer on the substrate;
a source contact and a drain contact that are on the barrier layer; and
a Group-III-nitride capping layer on the barrier layer and separated from the source contact by a first gap and from the drain contact by a second gap.

16. The Group-III-nitride HEMT of claim 15, further comprising an insulating capping layer that is on an upper surface of the Group-III-nitride capping layer and in the first gap and the second gap.

17. A Group-III-nitride high-electron-mobility transistor (HEMT) comprising:
a substrate;
a barrier layer on the substrate;
a source contact and a drain contact that are on the barrier layer;
a Group-III-nitride capping layer on the barrier layer, between the source contact and the drain contact; and
a gate on the Group-III-nitride capping layer,
wherein the Group-III-nitride capping layer is spaced apart from the source contact by a first distance comprising a first percentage of a third distance between the source contact and the gate,
wherein the Group-III-nitride capping layer is spaced apart from the drain contact by a second distance comprising a second percentage of a fourth distance between the drain contact and the gate, and
wherein the first percentage and the second percentage are each at least 1%.

18. The Group-III-nitride HEMT of claim 17, wherein the second percentage is larger than the first percentage.

19. The Group-III-nitride HEMT of claim 18, wherein the second percentage is at least 10%.

20. The Group-III-nitride HEMT of claim 19, wherein the first percentage is at least 10%.
